(19) United States
(12) Patent Application Publication
(10) Pub. No.: US 2024/0097062 A1
(43) Pub. Date: Mar. 21, 2024

(54) Systems and Methods for Customized Configurable Batteries, Solar Arrays, Control Chips, and Solar Vehicles

(71) Applicant: Noah Davis, Carbondale, CO (US)

(72) Inventor: Noah Davis, Carbondale, CO (US)

(21) Appl. No.: 18/472,079

(22) Filed: Sep. 21, 2023

Related U.S. Application Data
(60) Provisional application No. 63/408,762, filed on Sep. 21, 2022.

(51) Int. Cl. H01L 31/05; B60L 8/00; B60L 58/10; H01L 31/02; H02J 7/35

(52) U.S. Cl. CPC H01L 31/05; B60L 8/003; B60L 58/10; H01L 31/02008; H02J 7/35

(57) ABSTRACT

A system for a configurable battery includes a plurality of battery cells, the plurality of battery cells not permanently welded. The system further includes a mechanical compression frame, the mechanical compression frame for holding the plurality of battery cells. The system further includes a balancing lead, the balancing lead interconnected with the plurality of battery cells, the balancing lead including one of circuitry and a microprocessor, wherein the balancing lead reads the voltage of the configurable battery at multiple points and directs current to specific cells of the plurality of battery cells. The system further includes the plurality of battery cells are arrangeable to yield different voltages, capacities, and terminals. In one alternative, the plurality of battery cells are arrangeable in series and parallel and combinations thereof.

### RELATED APPLICATIONS

This application is a non-provisional application of U.S. patent application Ser. No. 63/408,762 filed on Sep. 21, 2022, which is hereby incorporated by reference to the same extent as though fully replicated herein.

### BACKGROUND

This disclosure relates generally to instruction in electronic technologies. In particular, educating students in constructing solar-powered radio-controlled cars are described.

Solar based technologies are becoming a more preferred method of harnessing and applying energy in the powering of vehicles and other uses. Such technologies are clean energy alternatives to fossil fuel powered conveyances and methods for transportation. Vehicles are an important way for people to travel to their desired destinations.

There are various types of assembly kits for model cars, as well as trains, planes and many other model-sized modes of transportation. But the assembly of such kits is dictated by the written instructions that accompany such kits. There is no opportunity to use such kits to learn about the technologies and processes in real-world functionality of the represented modes of transportation.

The best approach for learning such technologies is a hands-on process where the student can assemble the elements, learn about the scientific principles regarding each element and apply creativity in designing, building and testing how the elements operate and discovering the optimum configurations available. The present disclosure promotes maintaining user engagement, testing hypotheses, improving the performance of the constructed cars and solve problems in a variety of ways of functionality and creativity. Though it's vitally important for today's youth to engage in relevant energy education, there has not been an engaging hands-on program to provide training based on first principles in a standalone renewable energy system. Namely photovoltaics to lithium batteries to an electric-vehicle drivetrain. This disclosure comprises of a method using a materials kit as a physical basis for building a model-sized solar-powered radio-controlled car. The materials kit provides materials and components which can be combined in a variety of ways to design and construct unique solar-powered radio-controlled cars for educational purposes centered on academic and racing competitions. The physical materials kit can be supported by online curriculum. The method promotes instruction concepts of engagement, improvisation, modularity, repairability, reusability, simplicity for educational concept transfer. It is a method applicable in general education as well as workforce training.

Thus, there exists a need for a method of construction of model-sized cars that improve upon and advance the method of instruction and allow for a hands-on approach where a person can creatively design, build and test a wide number of possible configurations—even disassembling and reconfiguring the cars. The present disclosure is a method upon a creative platform where the process of building of model-sized solar-powered cars are not just an assembly item, rather the method will maintain engagement, allow for testing of hypotheses, instruct on how to improve performance and teach the methods of solving problems.

### BRIEF DESCRIPTION OF THE DRAWINGS

FIG. 1 shows one embodiment of a Solar Roller;

FIG. 2 shows some key components of the Solar Roller of FIG. 1, namely one embodiment of battery pack together and in a piecemeal exploded view;

FIG. 3 shows the underside of Solar Roller of FIG. 1;

FIG. 4 shows one embodiment of lattice;

FIG. 5 shows one embodiment of balancing leads 220 arranged in lattices;

FIG. 6 shows one embodiment of flat wires;

FIG. 7 shows one embodiment of flat wire leads attached to flat wires;

FIGS. 8, 9, and 10 shows one embodiment of top caps in different views;

FIG. 11 shows one embodiment of a PV Ticket;

FIGS. 13 and 14 show one embodiment of a PV Cell Soldering Template.

FIGS. 15-16 shows one embodiment of Topsheet/Template;

FIG. 17A shows one embodiment of rigid foam layer;

FIG. 17B-17e show one embodiment of Array Top Plugs;

FIGS. 18-20 shows one embodiment of Connectors;

FIG. 21 shows one embodiment of connector plugs;

FIGS. 23 and 24 show one embodiment of a conceptual model for the programable chip of the solar roller.

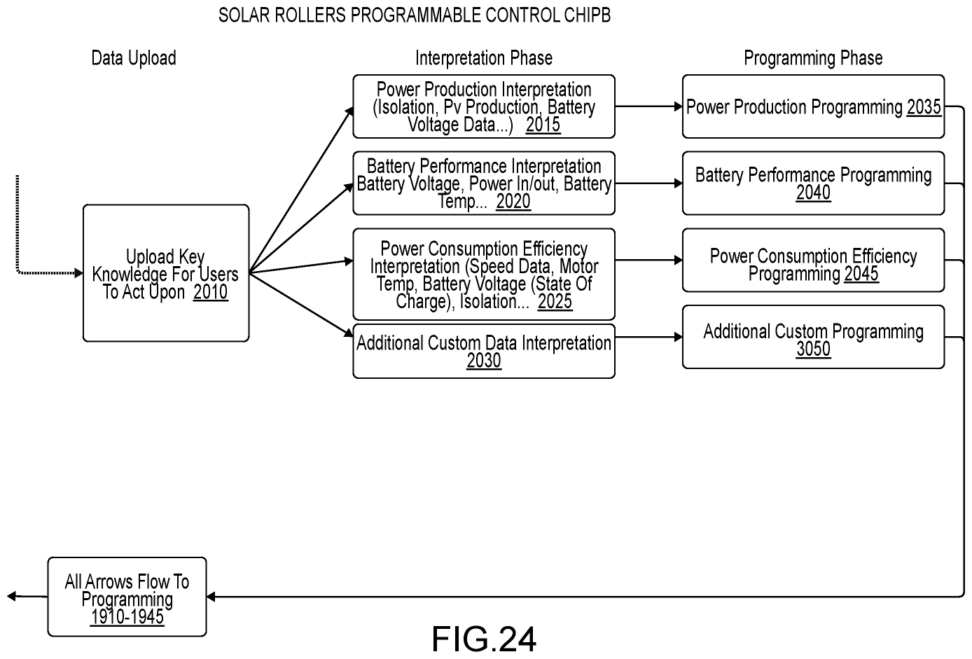

### BRIEF SUMMARY

In one embodiment, a system for a configurable battery includes a plurality of battery cells, the plurality of battery cells not permanently welded. The system further includes a mechanical compression frame, the mechanical compression frame for holding the plurality of battery cells. The system further includes a balancing lead, the balancing lead interconnected with the plurality of battery cells, the balancing lead attached to a microprocessor, wherein the balancing lead reads the voltage of the configurable battery at multiple points and directs current to specific cells of the plurality of battery cells. The system further includes the plurality of battery cells are arrangeable to yield different voltages, capacities, and terminals. In one alternative, the plurality of battery cells are arrangeable in series and parallel and combinations thereof. Alternatively, the mechanical compression frame holds the plurality of battery cells in an arranged position. In another alternative, the arranged position is changeable to a second arranged position which modifies as least one of a voltage, capacity, or terminals of the configurable battery. Alternatively, the mechanical compression frame is a lattice. In another alternative, the lattice includes a first side and a second side, each of the first side and the second side including a first and second slot, the first and second slot sized to receive an end of one of the plurality of battery cells. Alternatively, the balancing lead includes a first wire and a second wire, the first wire connectable to a first side of the lattice and the second wire connectable to the second side of the lattice. In another alternative, the system further includes a flat wire, the flat wire forming a main circuit of the configurable battery, the flat wire interconnected with the first and second wire, the flat wire arranged to yield a particular arrangement of the plurality of batteries cells, such that the plurality of battery cells are in a wired configuration selected from one of series, parallel, and a combination thereof. Alternatively, the wired configuration is changeable by rearranging the flat wire. In another alternative, the system further includes a plurality of top caps, the plurality of top caps removably holding the first and second wire against the flat wire.

In one embodiment, a system for an adjustable solar array includes a first photovoltaic cell, a PV Cell soldering template, and a top sheet template. The system further includes a rigid foam layer, a plurality of array top plugs, and a plurality of connectors. The system further includes a plurality of cable ties, and a plurality of caps. The PV Cell soldering template is arranged in relation to the first photovoltaic cell to provide soldering interconnect positions on the first photovoltaic cell, the top sheet template arranged to provide a base for the first photovoltaic cell and provide for a plurality of apertures for the plurality of array top plugs, the plurality of connectors, the plurality of cable ties, and the plurality of caps, interfacing to provide a stable frame for the adjustable solar array. Alternatively, the plurality of connectors, a plurality of array top plugs, and a plurality of caps form a crosswise frame which provides support to the rigid foam layer. In one alternative, the plurality of array top plugs provide for eight degrees of orientation for the plurality of connectors.

In one embodiment, a control chip for a solar car, the control chip executing software instructions, containing software instructions that when executed cause the control chip to: measure a PV Array voltage, measure a PV Array current, measure a battery voltage, measure a battery current, and log the PV Array voltage, the PV Array current, the battery voltage, the battery current. Optionally, the control chip is further configured to and caused to: measure a battery temperature, measure a motor temperature, measure a gps ground speed, measure a solar insolation, and log the battery temperature, the motor temperature, the gps ground speed, and the solar insolation. Alternatively, the software instructions further include that when executed cause the control chip to: hold the PV Array voltage at a selected voltage. Optionally, the selected voltage is the maximum powerpoint on the IV curve of the PV array. Alternatively, the software instructions further include that when executed cause the control chip to: set a maximum battery voltage and control the battery voltage such that it does not exceed the maximum battery voltage. Optionally, the battery voltage is controlled by disconnecting and connecting current from a solar array.

### DETAILED DESCRIPTION

This disclosure provides a method on instruction using a package of materials and curriculum which educates users as they design, build, test and sometimes race a small-scale solar-powered radio-controlled car (hereinafter may be referred to as a “Solar Roller”). In many embodiments, using the kit's unique items and hands-on processes, users learn the principles and key concepts of photovoltaic (PV) arrays, lithium batteries, and electric vehicle technologies. These vital industries need viable candidates who understand these technologies for use in full-scale renewable energy, battery and electric vehicle systems. Crucially, this kit is intended to allow people to creatively design, build and test a wide number of possible configurations—even disassembling and reconfiguring the cars. The kit is a creative platform, not just an assembly item, to maintain engagement, test hypotheses, improve performance and solve problems in a variety of ways.

The basic elements of the method require students follow the curriculum to design and build their Solar Roller in stages. One such embodiment of the method includes the steps where students create a basic car design, based largely on the electrical system of the car. The voltage of the standalone system is first determined based on the desired performance characteristics of the car. Photovoltaic (PV) circuit design then determines the number of solar cells in the array and thus the general size of the top of the car. PV cells, included in the kit, may be modified or run in parallel circuits to produce different levels of current when exposed to sunlight. The final array can be laid out in a variety of shapes which largely determine the shape of the car overall. A typical Solar Roller might be 80 cm×50 cm×10 cm but size varies based largely on desired amount of PV production.

Users design a custom lithium battery for their Solar Roller based on materials included in the kit. The standalone system's voltage determines the number of battery cells wired in a series string. The desired capacity then determines the number of strings wired in parallel. A typical Solar Roller battery might include series wiring for two LiFEP04 batteries (18650 size, 3.3V, 1100 mah each) to achieve a nominal voltage of 6.6. Two parallel strings of these batteries then provide a typical capacity of 2200 mah. Users running an efficient lightweight car with a smaller PV array might choose just one string for 1100 mah of capacity, while s running a larger heavier car with more PV production might use three parallel strings for a capacity of 3300 mah. Other users may choose a different system voltage, which requires varying the number of cells wired in series.

Users build the custom lithium battery from component parts included in the kit. These parts include battery cells (currently 18650 3.3V 1100 mah LiFEP04 lithium batteries), proprietary Battery Assembly Lattice, proprietary Battery Caps, proprietary Flat Battery Wire, balancing leads, and cable ties. The method of assembly is unique and allows users to build a complete, functioning, mechanically stable battery without welding or soldering the battery cells themselves. This means the battery assembly is completely reconfigurable and the key proprietary parts are reusable and interchangeable. This allows users to cut the cable ties on and disassemble their battery to test, repair, or to rebuild a battery in a completely new configuration. This is a unique method of assembling and reassembling batteries. Critical lessons include locating balancing taps within the battery for maintaining balanced voltages within individual battery cells.

Users prepare the Photovoltaic Cell Components for the top of the car. Each bare cell (currently back-contact 125 mm SunPower Maxeon cells) is soldered to twin conductive interconnects which extend beyond the cell in opposite directions. One interconnect becomes the positive contact for the cell, while the other is the negative contact. The kit provides a precise and proprietary physical template for locating the interconnects in their exact correct position on the cell during soldering. This ensures that each PV cell is uniform in physical layout—which is often difficult for users to achieve without a template. Each PV Cell Component with twin interconnects is a single complete component to add in or remove from the array, much like any AA battery is placed into a flashlight circuit. This is a unique use of cells and interconnects.

Users build the PV array from their component PV Cells. Using a proprietary Array Backing Sheet, users apply their PV Cell Components onto their sheet (currently using adhesive transfer tape). The interconnects which extend from each cell are pushed into the Array Backing Sheet slots, making a physical and electrical connection from one PV Cell Component to the next. Once the cells are in place, solder can be added to these connections to ensure contact is maintained even during driving and road impacts. A variety of flat bus-wire techniques are used to complete the electrical circuit and bring the array's “home-run” power wires into the car's main circuit. The array receives a protective covering, usually a paint-on chemical layer such as Q-Sil (currently best) or Dow SilGard or a polymer sheet layer such as shrink-wrap plastic or polycarbonate.

Users design, lay out, and cut the chassis tubing. The kit includes a number of chassis assembly pieces including structural carbon square tubing (currently 6 mm) and proprietary assembly clips. These square tubes can be laid out and cut to length to create a lightweight and strong ladder-type chassis assembly which attaches beneath the rigid foam layer.

In some embodiments, users build the chassis “sandwich” structure. Users create a very strong and rigid three-layer sandwich with the strong square-tubing chassis on the bottom, the rigid foam (currently EPS foam about 12.5 mm thick) layer in the middle, and the PV Array, (now secured on the Array Backing Sheet) on top. holes aligned to the corner positions of each cell. Proprietary Chassis Plugs are dropped through the precut diamond-shaped holes in the Backing Sheet and into the holes in the rigid EPS foam. This pins the Array Backing Sheet onto the rigid foam layer. A folded zip tie extends from each plug through the holes, ready to receive the chassis components on the bottom side of the foam. The chassis tubing and clips are secured to the foam layer by tightening cable ties from the Chassis Plugs around them.

In some embodiments, users attach the radio-controlled car to the chassis structure by aligning the chassis tubing with the key components of the radio-controlled car. These components are sized to fit the rail system and attach as one or more “component islands” within the rails. For example, the simplest method of attachment sees the car's chassis tray drop within the rails, with all components of the RC car attached to its own chassis tray. More complex and versatile cars may attach just one component in one location between chassis rails—such as an island attaching just one front wheel with steering and suspension. Similar islands could attach just a rear wheel with suspension, a battery, or a front differential with steering rack and servo. In this way a user can design a car with a wider or narrower stance, a longer or shorter wheelbase, 2-wheel drive or 4-wheel drive, varied driveshaft lengths, etc. Users may also use “hop-up” or aftermarket parts to tune their motor, gearing, sway bars, steering, shocks, camber, caster, tires etc.

In some embodiments, users program and obtain data from their proprietary Solar Rollers Control Chip which allows them to adjust and monitor the performance of the solar array, battery and car. This chip provides access to key energy production and use information from the PV Array and Battery, as well as control of the Maximum PowerPoint Tracking function for the array. The chip is powered by an independent battery to continue functionality during PV direct use of the car, and provides basic telemetry information to the user's device via Bluetooth.

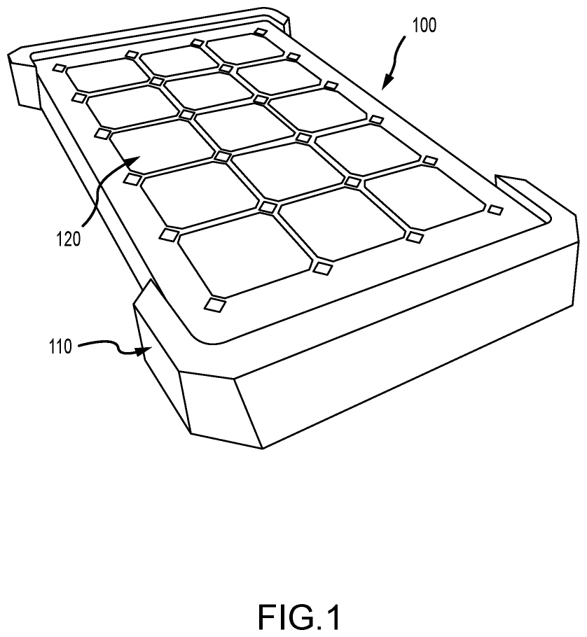

FIG. 1 shows one embodiment of a Solar Roller. In this view, the top of Solar Roller 100 is visible. The top includes a frame 100 with bumpers 110 and a solar panel array 120.

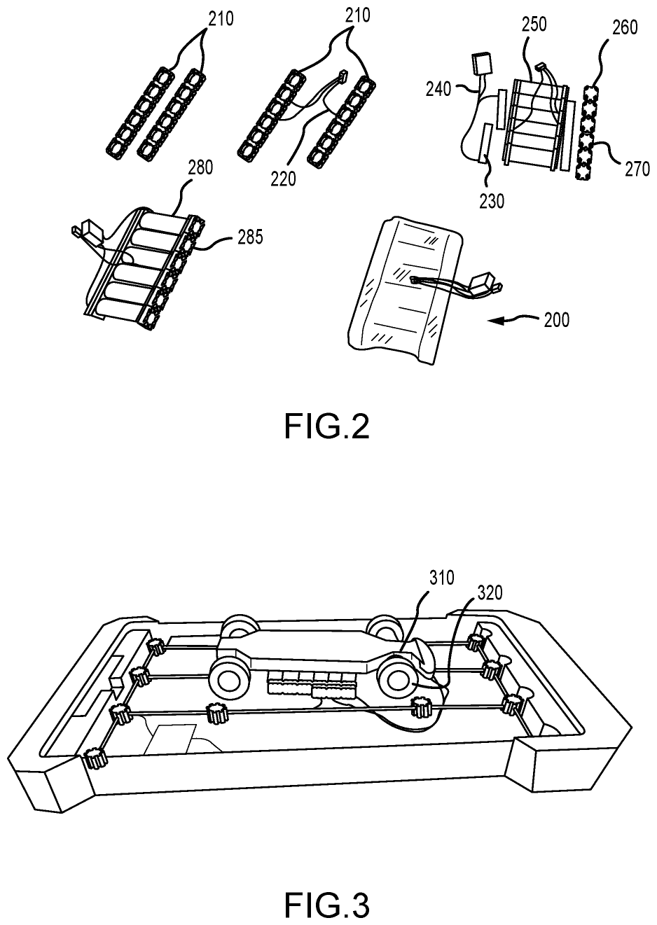

FIG. 2 shows some key components of Solar Roller 100, namely one embodiment of battery pack 200 together and in a piecemeal exploded view. Battery pack 200 may be referred to as a do it yourself battery design and assembly system. This battery pack 200 may be deployed in various contexts, including those outside of Solar Rollers. The DIY Array Platform Design/Assembly System may be used to design and build a PV Array/Platform in order to solar charge an appropriate battery, or to solar power any other appropriate electrical load. Instructions are a vital part of the system and required to teach the safe design of the energy system and the proper use of the parts in the kit of materials. Instructions may be specific to a course, camp, or program and they may be accompanied by relevant educational content such as curriculum covering solar, battery and EV technology and careers. Battery pack 200 includes lattice 210, which will be described in greater detail below. It further includes balancing leads 220 to balance power from the system. It further includes flat wires 230 for interfacing with battery cells 250 and flat wire leads 240. Top caps 260, 270 assist in sealing the device. Additionally, cable ties 280 wrap around the body of the battery pack 200 to hold it together as show in assembly 285. These parts will be discussed in further detail below. One purpose of the DIY Battery Design/Assembly System is to allow users to quickly and easily assemble a functional multicell battery from individual cells. The system is unique in that the cells are not permanently welded into the battery circuit—rather the electrical connections in the circuit are secured using firm mechanical compression between electrical conductors. In this way, the individual cells are not physically altered during the assembly or disassembly of the battery. The design can be changed and the cells reconfigured to build and rebuild different battery configurations with different key characteristics (voltage, capacity, terminals). The resulting batteries can be used as one would use a commercially available battery of identical voltage and capacity. This system allows the same individual cells to be used to power varying electrical loads in varying applications. Examples of appropriate loads are radio-controlled cars, electric bicycles, device-charging powerbanks, electric motors, ride-on toys, power tools and other items requiring portable electricity. The system is particularly useful for engaging hands-on education. The system may use a variety of different individual battery cells. The first iteration uses 18650 lithium cells (specifically LiFEP04 chemistry) but can also be adapted to use other sizes of cylindrical cells (such as 26650 cells) with a variety of chemistries. The fire-resistant properties of LiFEP04 make this chemistry ideal for teaching battery design and assembly while the durability of this chemistry makes it ideal for racing and learning. The system works with various chemistries, voltages and capacities of lithium batteries by incorporating balancing leads in addition to its main power leads. Depending on the application, the battery's main power leads may terminate in a variety of higher-current connectors such as banana plugs, TRX connectors, Dean's Plugs, XT60s, XT90s, etc. The finished batteries can be bulk charged and discharged—without balancing—solely through the main power leads. Whenever lithium cells are used, periodic battery balancing is required. The system incorporates balancing leads (balancing taps) at key points within the electrical circuit, which terminate in a multicontact balancing plug. (When the battery is built in a 2S format, a 2S balancing plug with three wires is wired into the system. A 3S battery configuration is built with a 4-wire 3S plug—and so on.) Just as in a commercially constructed lithium battery, these batteries are plugged into the balancing charger using both the power lead plug and the balancing plug. The balancing charger thus reads the voltage of the battery at several key points in the circuit through the balancing leads (taps) and directs current to specific cells (or modules of multiple parallel-wired cells) to ensure a balanced charge level within all of the cells in the battery. The parts comprising this system can be packaged together in specific amounts and proportions to support the build of a specific battery (for example a 2S3P 6.6V, 3300 mAh inline battery). Alternately, a nonspecific custom design/build kit can be assembled to allow for the design and build of one or more custom batteries. In this case the kit would include multiple lattices or a larger lattice grid that can be cut down to hold the desired number and arrangement of cells. Custom users design the physical and electrical layout first, plan the appropriate cell layout (location and polarity/orientation of cells), then cut or choose lattice accordingly, select the appropriate balancing leads (2s, 3s . . . ), cut flat wire to length, solder custom flat wire leads with the appropriate connector, and assemble the battery.

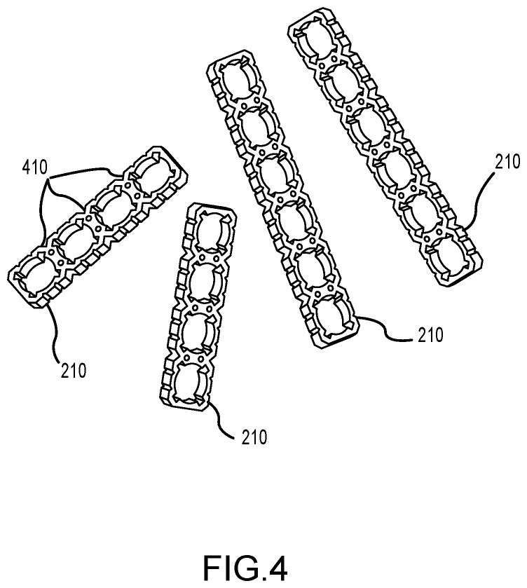

FIG. 3 shows one embodiment of the underside of Solar Roller 100. The chassis 310 of the car portion is visible as well as the wheels 320. This aspect of Solar Roller 100 may vary greatly depending on desired setup, as any car chassis and wheels system may be possible. Commercially available systems may be used as the car portion that imparts mobility to the device as well as may custom or stock car configurations.

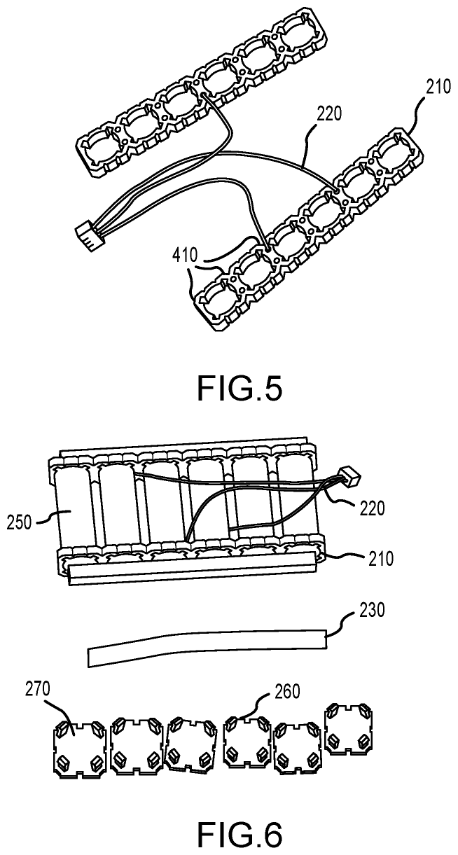

FIG. 4 shows one embodiment of lattice 210. Lattice 210 may be composed of flexible material such as TPU (thermal plastic polyurethane) and includes repeating pattern of linked individual cells. In the embodiment shown, the lattice is flat in profile and 5 mm high. 22 mm square outer dimensions per cell, circular 18 mm interior hole with recesses in the interior of the 4 corners to accept tabs from the top cap. Two 1 mm round channels on each exterior wall form holes in junction walls to accept the Balancing Leads. The lattice 210 includes voids 410 for interacting and snap fitting or otherwise holding to tabs 910 of top caps 260, 270. Two lattice pieces per battery, one on each end of the cell. Alternative shapes and sizes are possible. The battery lattice is a key structural component of the battery which holds the individual battery cells together and holds the balancing taps and top caps in their positions. Constructed from a tough, thick layer of flexible material such as TPU when 3D printed, or synthetic rubber when lasercut, the lattice tightly holds the individual battery cells in position. The lattice is comprised of a repeated joined 4-sided shape, each square holding one individual battery cell. It can be repeated to make a wide variety of multicell battery layouts with different inline or grid, parallel and/or series battery layouts. A battery with identical electrical characteristics can be made with different layouts for different applications and battery compartment constraints. For example a 2S3P battery may take the form of 6 cells in one long row, or two rows of three cells. The thin bare wire ends of the battery's balancing taps are also threaded through the lattice—where they are exposed to and held tightly against the flat wire that makes up the main electrical circuit of the battery. The lattice may be provided to the user in a specific battery configuration for simple assembly. For custom design, a larger latticework may be provided and the user can cut the latticework down to create the desired configuration. In alternatives, the lattice 210 may take on a variety of different shapes. The point of lattice 210 is to provide a reorganizable framework that can hold the battery cells 250 in position, such that leads may be attached to them and they hold position in operation. So the aperture of lattices 210 should be approximately sized to receive the battery cell intended to be held.

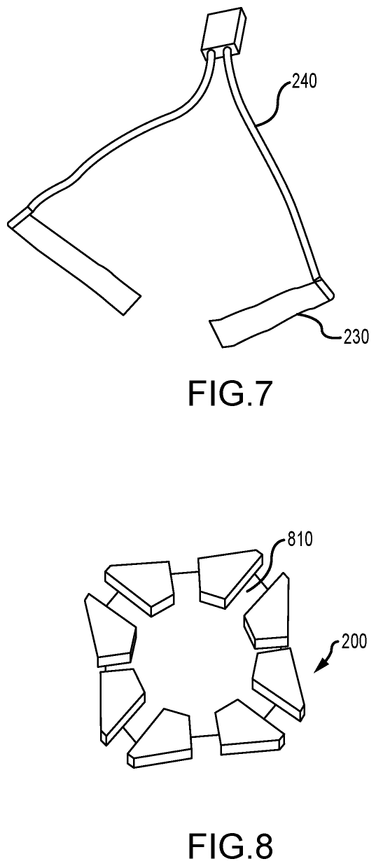

FIG. 5 shows one embodiment of balancing leads 220 arranged in lattices 210. Balancing leads 220 (taps) are thin wires that reach into the electrical circuit to measure voltage and direct the charging current to individual cells or groups of parallel-wired cells (modules). In the DIY Battery Design/Assembly System the balancing taps are threaded into the lattice explained above, with each wire positioned to contact the appropriate section of flat wire 230 within the battery. The top caps 260, 270 then trap the balancing leads 220 tightly against the flat wire 230, establishing the electrical connection through compression. Once assembled, the battery assembler can use the balancing plug to easily test that the battery is properly wired and that each module is showing proper continuity and voltage prior to charging

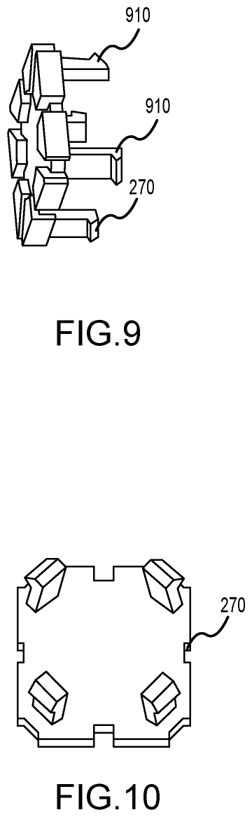

FIG. 6 shows one embodiment of flat wires 230. Conductive Flat wire 230 (tinned, foldable conductive bus wire) forms the main circuit of the battery pack 200. In the first iteration using 18650 battery cells, this wire is ˜10 mm×˜0.2 mm and it is cut to length as needed to electrically connect the terminals of individual cells. In batteries with higher current (more cells in parallel) the wire can be doubled or tripled back on itself to carry double or triple current as necessary. Various arrangements may be configured from flat wire 230. The size and shape of flat wire 230 may vary, the point is to contact the ends of the battery cells 250 and allow for the flat wire 230 to be folded and arranged to provide for more or less current, depending on how the flat wire is folded upon itself. More folds mean more current. FIG. 6 also shows battery cells 250, lattice 210, balancing leads 220 and top caps 260, 270.

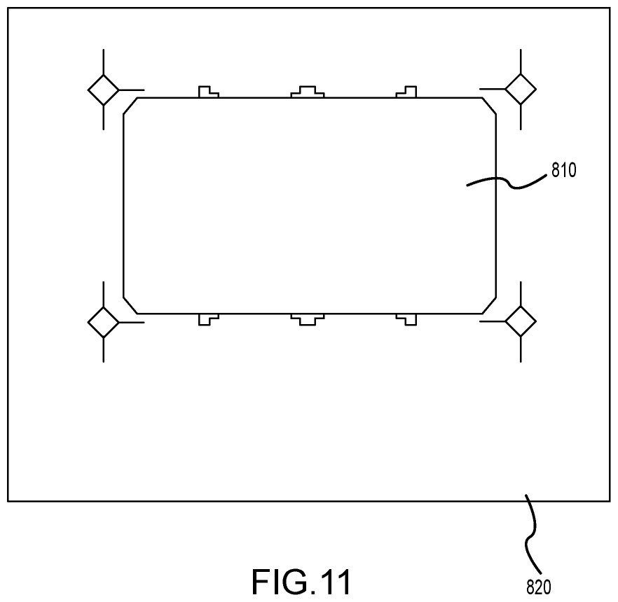

FIG. 7 shows one embodiment of flat wire leads 240 attached to flat wires 230. The Battery Design/Assembly system can be equipped with presoldered main power leads/connectors for easier/faster assembly. For hands-on education or maximized customization, students can hand-solder the flat wire to higher-current main power leads and connectors. In this case the flat wire is folded over the bare wire end of the power lead and soldered to it, connecting the battery cell terminal(s) to the power lead and the power lead connector.

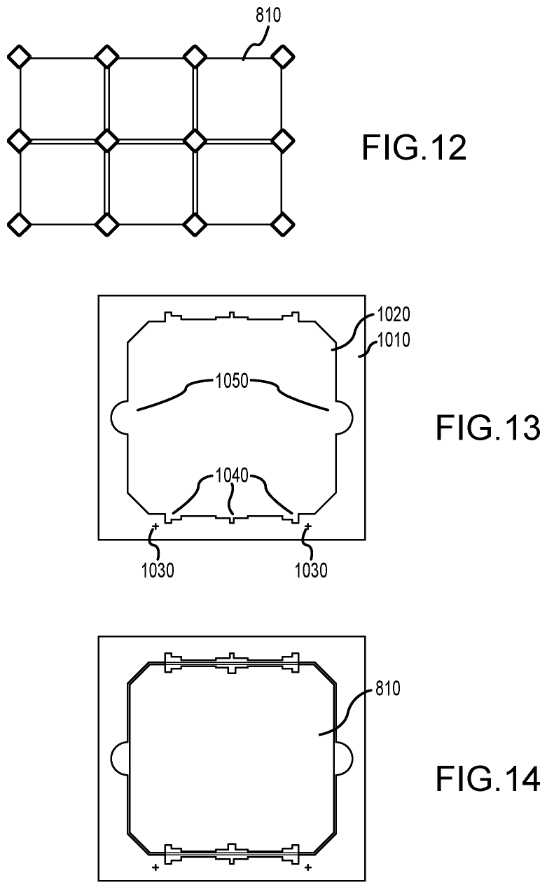

FIGS. 8, 9, and 10 shows one embodiment of top caps 260, 270 in different views. In the configuration shown, top caps 260, 270 are rigid nylon, 22 mm square, 9 mm high. Channels 810 to trap cable ties on top and 4 tabs 910 protruding on the bottom to tightly fit around an 18650 battery cell and into the corresponding recesses in lattice. When fully inserted in the lattice the tabs seat tightly due to end protrusions. Top caps 260, 270 are structural and nonconductive. Each has 4 protruding tabs 910 that push down into corresponding voids in the lattice 210, interlocking with the lattice to pinch the balancing leads 220 (taps) tightly against the flat wire 230 and trapping the flat wire 230 in place on the battery cell 250 terminals. Additional compression from cable ties is required to ensure continued connection. The negative top caps 260 are placed on the negative terminals of individual battery cells and indicate polarity by color (black or gray). The positive top caps 270 are placed on the positive terminals of individual battery cells and indicate polarity by color (red). Cable ties 285 loop around the battery cells 250 and top caps 260, 270 longitudinally to pull the top caps 260, 270 together, exerting constant compression force that ensures robust electrical connections to the flat wire 230. Commercially available thin cable ties (supporting 18 lbs breaking force) are sufficient for batteries made with 18650 cells, and larger battery configurations could use 50 lb cable ties. Users may opt to combine cable ties in a variety of configurations to better compress or decorate the battery or to save weight. Once assembled, two major conductive points on the battery circuit will remain exposed. Users are recommended to electrically insulate over these points by “potting” them with hot glue prior to shrink-wrapping the entire battery in thick nonconductive plastic (show in FIG. 2). Multiple stacks of battery cells may be assembled, in both rows and columns, even though in the figures only a single line of battery cells is shown. This allows for a variety of different configurations of the batteries.

Embodiments of Solar Roller 100 also include embodiments of a DIY Array Platform Design/Assembly System. The array platform resulting from this system is a lightweight, rigid composite structure that incorporates a functioning solar array on its surface. In a repeating pattern, each modular unit supports one replaceable photovoltaic (PV) cell. The platform layers consist of the solar cells themselves, a custom cut nonconductive topsheet, a rigid foam intermediate layer, and a network of strong tubing on the underside which is tensioned through the foam layer to a series of array top plugs, compressing the layers together. Users can design the desired electrical and physical characteristics for a custom solar array, then build the functioning array upon a strong, light efficient platform using this system. The resulting PV array is lightweight and rigid and can be used to solar charge batteries or power PV-direct electrical loads with no intermediate battery. The DIY Array Platform Design/Assembly System was originally created for hands-on education as a means for students to solar-powered radio-controlled cars. The resulting arrays can also solar power a variety of lower-voltage battery-based and/or PV-direct tools, toys, educational products or other electrical loads.

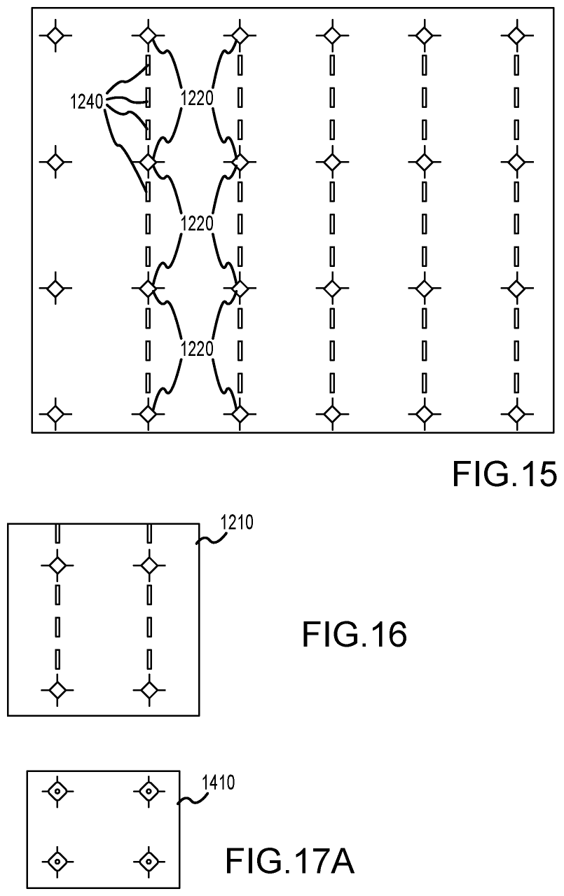

FIGS. 11 and 12 shows one embodiment of a solar cell 810 in a PV Ticket 820. One solar cell with two interconnects soldered to the contact pads. One positive and one negative interconnect are part of each PV ticket. The PV ticket is the key modular component which makes this system much easier to use in construction of a solar array—when compared to using raw cells. By adding two interconnects to a photovoltaic cell (one to the positive terminals and one to the negative terminals) the cell becomes a unit with accessible electrical contacts—far easier to assemble, solder, unsolder and replace. PV tickets may be soldered with one interconnect extending beyond the cell in each opposing direction. In some placements, the user may opt to solder one interconnect extending and one tucked underneath the cell. This format can be useful where cells connect electrically to one side instead of continuing forward in a straight line. PV Tickets should be protected with a layer of solar-specific encapsulant on top—such as Q-Sil or Dow Silgard. PV Tickets can be fully prepared—including soldered interconnects and a protective layer of encapsulant—as spares. These spare PV Tickets can serve as rapid replacements during racing or other time-constrained activities.

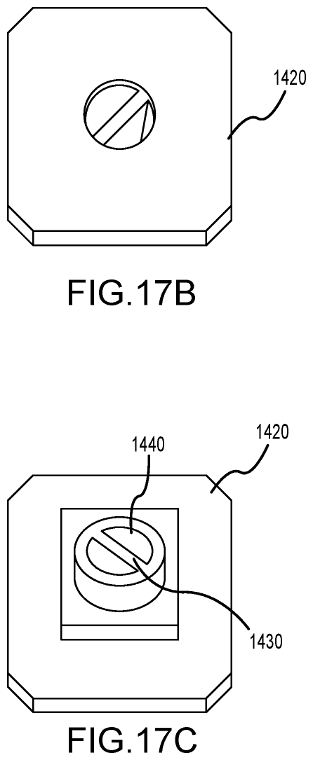

FIGS. 13 and 14 show one embodiment of a PV Cell Soldering Template 1010 with a solar cell 810 installed in FIG. 11. PV Cell Soldering Template 1010 is Lasercut from 0.8 mm plastic (ABS). 125 mm and includes a roundagon cutout 1020 with polarity marks 1030 and recesses for interconnects 1040 and finger access 1050. The PV Cell Soldering Template enables the user to easily and accurately produce a PV Ticket for use in the PV array. The template is a flat piece of material with a central cutout that matches the dimensions of a solar cell. Additional shapes are cut out on the ends of the cell to hold proprietary interconnects in the correct position for accurate soldering. High temperature Kapton tape can be strung along the interconnect area to better hold the interconnect in position during soldering. Soldering the two interconnects to the cell makes one PV ticket. Alternative templates may be used, but the idea is to allow ready assembly by providing guide areas for attachment of leads and cutouts for access and to receive solar cell 810.

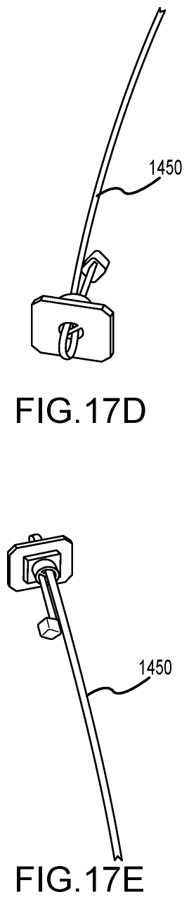

FIGS. 15 and 16 show one embodiment of Topsheet/Template 1210, which is Lasercut and laser engraved from 0.8 mm ABS plastics. 130 mm square PV Ticket units 1220 repeating. The topsheet 1210 is a thin plastic (ABS in the first iteration) with dimensioned holes cut into it. The topsheet serves as a base for the array, holds the array plugs in place, and adds sheathing strength to the array platform. The topsheet has penetrations 1240 for the array plugs and cable ties that compress the entire PV platform assembly. These holes are also used as a stencil jig to accurately mark and pierce the rigid foam layer beneath. Ovalized holes 1230 between PV Ticket placements provide spaces for the interconnects to meet and be soldered together. Additionally, instructions and cutout guidelines are engraved into the topsheet to assist users in the design and build of their array and platform.

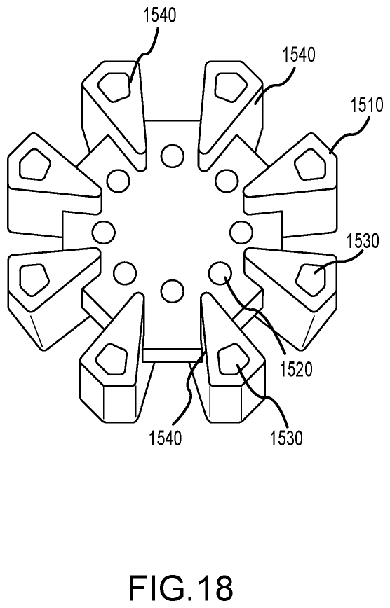

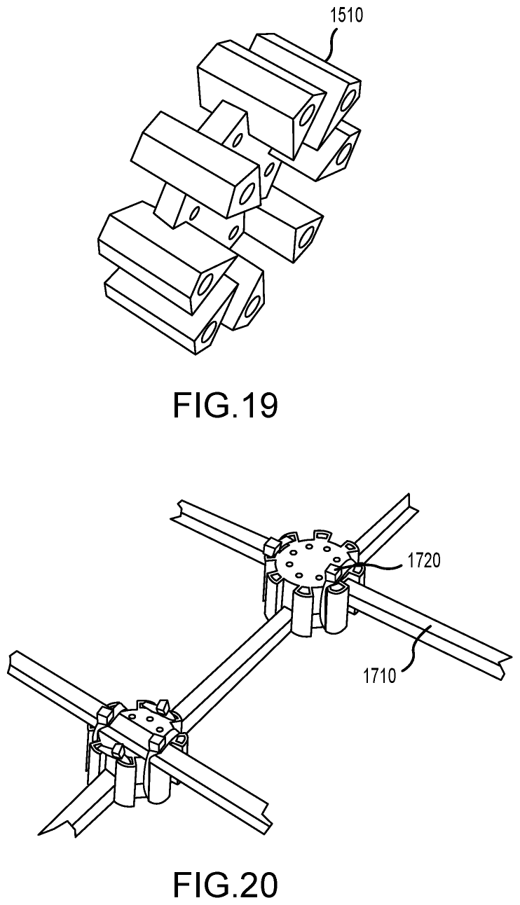

FIG. 17A shows one embodiment of rigid foam layer 1410. A lightweight layer of rigid foam (Expanded Polystyrene EPS in the first iteration) provides stiffness and depth to the array platform. The rigid foam layer 1410 is sandwiched in between the Topsheet/Template 1210 and the carbon tube chassis rails, with holes through the rigid foam allowing the array plugs to tie down to the chassis rails using cable ties. The parts associated with the platform (array plugs, cable ties, connectors and connector plugs) are designed to be used with any thickness of foam layer, 10 mm thick or more. The thickness of the foam layer may be increased to strengthen the platform, increase the overall rigidity of the platform, or provide thicker attachment points for bumpers, siderails or other accessories. Rigid foam layers can be customized extensively, cut into any shape, and stacked and glued to effectively increase its thickness in critical areas, such as the impact zones where bumpers mount, or butted against chassis rails to hold them securely in place.

FIG. 17B-17e show one embodiment of Array Top Plugs 1420. Array top plugs 1420 are formed of rigid nylon and are 18 mm square flat top (designed to mimic the roundagon outline of a solar cell). 18 mm deep central tunnel 1430 with a divider 1440 accepts a cable tie 1450 for tensioning. A 9.4 mm square protrusion seats tightly into the diamond recess on the topsheet. Array top plugs 1420 fit tightly into and on top of the diamond shapes that are cut into the PV Array Topsheet 1210. A cable tie 1450 loops through the passage 1430 in the top plug 1420, straddling an internal divider 1440 that allows the plug to be tensioned down through a hole in the rigid foam 1410. The other end of the cable tie 1450 loop attaches to the square tube system below the rigid foam 1410. The cable tie may loop around a square tube directly, or it may pass through/around a connector 1510, connector plug and/or connector cap 1810. In this way the topsheet is compressed tightly, also securing the square tubes on the other side of the platform.

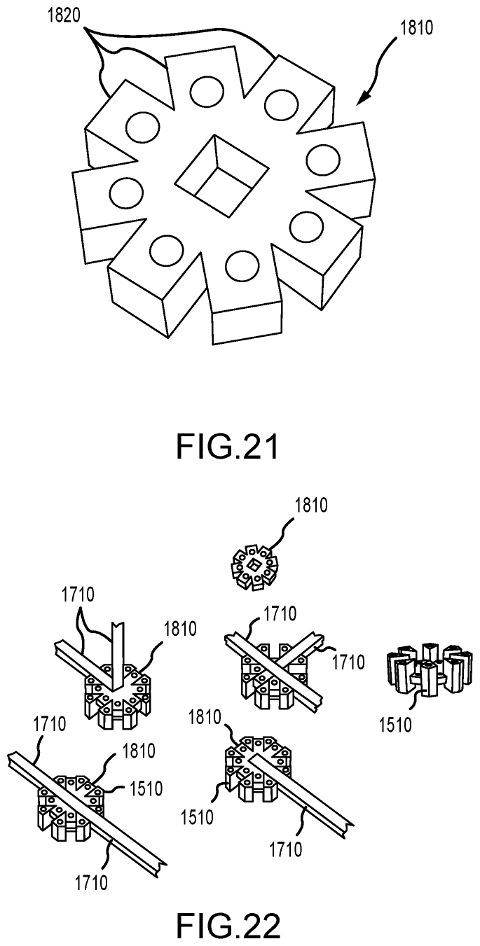

FIGS. 18-20 shows one embodiment of Connectors 1510, which are 32 mm×12 mm composed of rigid nylon. Connectors are the key component in building junctions to form a strong PV platform assembly and attach it to an RC car or another object. The connectors tightly attach to 6 mm square tube carbon rods 1710 (and could easily be scaled up to handle common 10 mm square tube or other sizes instead.) The connector can accept square tube in channels 1520 at 45 degree increments—on two parallel planes on either side of a central platform. The central platform has 8 holes 1530 for cable ties 1720 to pass through. Each of the 8 radial wedges 1540 has a vertical hole 1530 for cable ties 1720 to pass through. In addition, cable ties can encircle the protruding wedges for a quick and secure external wrap. Connectors have 6 mm deep channels 1520 on one side (wedges 6 mm high) and 3 mm deep channels 1520 (wedges 3 mm high) on the other. Connectors are used in multiple ways, often in combination, by connecting with cable ties:
1. Through the rigid foam layer to the top of the PV platform. The cable tie extends up through a hole in the rigid foam, past the topsheet and loops back down through an array top plug—compressing the array platform and trapping one or more carbon rod(s) in place against the foam layer. Connectors are thus fixed in place below the Array Top Plug, though the exact position of the connector can differ according to the chosen holes used in the connector.
2. To one or more carbon rods on the same plane. Connectors may clip up onto a single rod that passes through—as they often do in attachment points for the RC car or other accessories. Or they can serve as a junction for more than one rod meeting at 90 degrees (T junction) or any multiple of 45 degrees (diagonal reinforcement rods, for example).
3. To one or more carbon rods on parallel planes. Connectors often “permanently” trap carbon rods on the highest plane and also hold reinforcement rods or connection rods on the other side of the central platform. This allows the connectors to hold more rods for structure and attachment points.
4. To the RC Car. Once carbon rods have been attached to the RC car, connectors (and/or connector caps) are used to hold it onto the rods in the PV platform structure. Connectors are installed using cable ties anywhere along the rods forming the PV platform structure. The rods attached to the RC are then clipped into the aforementioned platform connectors and secured using just cable ties—or with additional connectors, connector caps and connector plugs on the RC car rods. Connector caps are very similar to connectors but they have wedges on only one side, forming 3 mm deep channels (wedges 3 mm high). The other side of the central plane is flat. Connector caps are used to cap connectors when there is no need for another layer of rods.

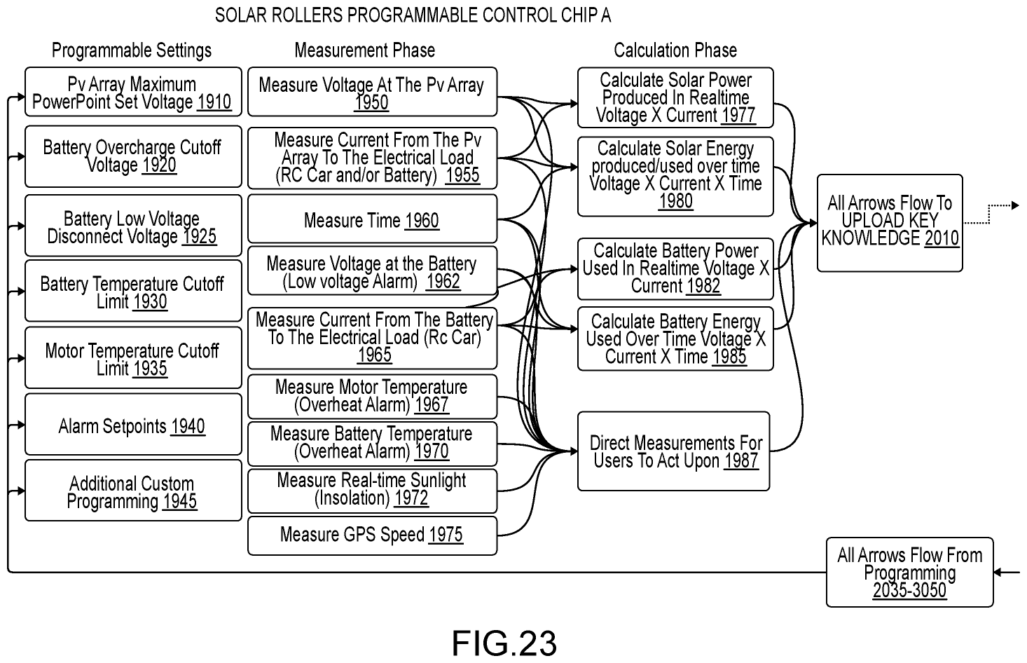

FIG. 21 shows one embodiment of connector plugs 1810. Connector plugs 1810 are made of flexible material (TPU95 in the first iteration) with 8 short radial spokes 1820 intended to fill the rod channels 1520 of connectors 1510 and connector caps. Each radial spoke contains a hole to allow a cable tie to pass through as it comes in from a connector or connector cap. A 6 mm square hole sits at the center as a guide for custom cuts—this hole also allows the connector plug to seat on the end of a carbon rod. Connector plugs 1810 can be used whole as an alignment tool, a strengthener and shock absorber/flex point for critical connections such as RC Car to PV Platform. Connector plugs can be cut down using cutting pliers for custom usage—for example one arm could be cut away to provide a reinforced stop point surrounding the end of a single rod. The connector plug 1810 supports the rod/joint and spreads any impact loads throughout the connector piece. Custom pieces of connector plugs can support and reinforce a variety of different junctions of rods. Connector plugs are made of flexible material (TPU95 in the first iteration) with 8 short radial spokes intended to fill the rod channels of connectors and connector caps. Each radial spoke contains a hole to allow a cable tie to pass through as it comes in from a connector or connector cap. A 6 mm square hole sits at the center as a guide for custom cuts—this hole also allows the connector plug to seat on the end of a carbon rod. Connector plugs can be used whole as an alignment tool, a strengthener and shock absorber/flex point for critical connections such as RC Car to PV Platform. Connector plugs can be cut down using cutting pliers for custom usage—for example one arm could be cut away to provide a reinforced stop point surrounding the end of a single rod. The connector plug supports the rod/joint and spreads any impact loads throughout the connector piece. Custom pieces of connector plugs can support and reinforce a variety of different junctions of rods 1710. Examples of single-plane square tube connections using Connectors 1510 and Connector Plugs 1810 in combination are shown in FIG. 19. The entire connection would be secured with the rods trapped against the rigid foam or another connector: Connector plug pieces can also be inserted in parts of the connector to add friction to joints. For example if a rod passes all the way through a connector channel it may slide fairly easily along the rod. The other 6 channels can be filled by pieces cut to fit tightly against the rod. Once cable ties secure the connector and connector plug, the connector will be less likely to slide along the rod in an impact. Connector plug pieces become attached to the connector when a cable tie loops through both.

The user may connect the solar roller in various ways that they see fit. Flexibility is key to making a competitive solar roller

In one embodiment, the solar roller a fully functional solar-powered car—with or without a computerized control chip. Using a control chip adds valuable data, systems control and functionality for the user.

When operating without a control chip, the PV Array and the Battery are wired in parallel to power the RC Car as a shared electrical load. During periods of low power use by the RC Car, excess energy from the PV Array charges the battery and does not go to waste. During periods of high power use by the RC car, such as acceleration, both the PV Array and the Battery provide power. Voltage to the battery is limited only by the maximum voltage (Voc) that the PV Array can provide, so users must match their PV array to their battery voltage to prevent potential overcharging.

The addition of a control chip provides added benefits to users of the Solar Rollers system. These include Datalogging, Maximum PowerPoint Tracking (MPPT), Overcharging and overdischarging cutoffs, Independently Powered Chip, App and GUI, and Telemetry.

Datalogging provides the user insights into the health of components as well as a much greater understanding of the energetics (energy flow) throughout the Solar Rollers system. The voltage and current to and from the PV Array and the Battery can be measured and logged at regular intervals, enabling calculation of the energy produced by the PV Array over time as well as the amount of energy stored and drawn from the battery. Additional useful data points can also be logged from the chip, including battery temperature, motor temperature, gps groundspeed and solar insolation (sunlight exposure),

MPPT: Users can manually set a desired voltage for the solar array and the chip will hold the array at that voltage regardless of sunlight levels or current drawn from the array. If chosen correctly (at the maximum powerpoint on the IV curve of the PV array) the array will produce more power than it would when uncontrolled, thus benefiting the user.

Users can set a maximum battery voltage, above which the chip will open the PV Array circuit—thus cutting off the solar power to the battery. Using a maximum voltage cutoff allows users more freedom in designing the solar array as overcharging is not a threat. Users can also set a minimum voltage cutoff to protect the battery. However due to the durable battery chemistry used by Solar Rollers and the desire to keep moving at any costs during a race, this feature may be set very low for racing.

Using Bluetooth communication or cabled through a usb port, the chip can upload logged data to the user's device when it passes close by, such as lapping the pit area in a circuit race.

The chip can be powered by its own independent small battery, thus continuing to function and log data even when sunlight and battery voltage drop very low. This depleted main battery condition often occurs during endurance racing of Solar Rollers and variable weather.

The control chip's data and control settings can be linked to an application running on digital devices. Using a graphic user interface, users can access data and change settings, such as MPPT or PV cutoff voltage, within the chip.

In many embodiments, the chip includes a number of traits. The chip may include an integrated power circuit. The chip plugs into the circuit both to access measurement points and to control the circuit itself. For example the chip plugs into the main PV array circuit enabling it to 1. Measure Voltage, 2 Measure Current, 3 Open the Circuit (shut off PV), 4 hold a Maximum Power Point Voltage, Chip will manage the MPPT Setpoint using programming alone or with small ring transformer if necessary. The chip may include Data Logging with Uploadable Accessibility. The chip logs all data/calculations over time and provides this info to user through bluetooth telemetry, USB-C port, or other periodic data upload methods. Algorithmic calculations can be done internally while raw data remains accessible for additional external usage once uploaded. The chip may be programable. Users are able to use key measurements/calculations to modify the circuit by programming the chip. For example, setting the Maximum Power Point Tracking Voltage, the Overcharge Cutoff Voltage, and the Low Voltage Disconnect Voltage. Sophisticated users can further control the PV Production, Battery Management and Power Usage with further custom programming. The chip may have a small form factor. The chip and accompanying battery/sensors/inputs/Alarm need to remain small and light enough to be affixed to the underside of the PV Array Platform as an “island” attached to the rods and/or connectors. The chip may be independently powered. The chip can be independently powered by its own battery (an A23 12V battery, for example). This prevents the chip's electrical usage from impacting systemic data measurements. It also allows the chip to continue accurately recording, logging and uploading data despite the widely varied voltage levels experienced during PV-Direct usage.

In many embodiments, the programable chip includes numerous use cases. This includes the use cases shown in FIG. 19 and FIG. 20. The programable chip provides for a number of programable settings. This includes PV Array Maximum PowerPoint Set Voltage 1910. PV Array Maximum PowerPoint Set Voltage 1910 provides for the user to set, via a GUI, textual interface, or other interface to set the maximum voltage for the PV Array. This includes Battery Overcharge Cutoff Voltage 1920. Battery Overcharge Cutoff Voltage 1920 provides for the user to set, via a GUI, textual interface, or other interface to set the maximum voltage charge on the battery, to prevent the battery from overcharging and therefore degrading. This includes Battery low voltage disconnect 1925. Battery low voltage disconnect 1925 provides for the user to set, via a GUI, textual interface, or other interface to set the minimum voltage charge on the battery, to prevent the battery from discharging to a low point that damages the battery. This includes Battery temperature cutoff limit 1930. Battery temperature cutoff limit 1930 provides for the user to set, via a GUI, textual interface, or other interface to set the maximum temperature on the battery, to prevent the battery from melting down, catching fire, or sustaining other damage. This includes Motor temperature cutoff limit 1935. Motor temperature cutoff limit 1935 provides for the user to set, via a GUI, textual interface, or other interface to set the maximum temperature on the motor, to prevent the motor from melting down, catching fire, or sustaining other damage. This includes Alarm setpoints 1940. Alarm setpoints 1940 provides for the user to set, via a GUI, textual interface, or other interface to set the alarms to be activated if one or more of the previously described limits, disconnects, and cutoffs are reached. This includes additional custom programing 1945. Additional custom programing 1945 provides for the user to set, via a GUI, textual interface, or other interface other alarms, cutoffs, disconnected, limits, or other controls on the attached circuit.

The programable chip may further includes measurement phase use cases. In case 1950, the programable chip may measure the voltage at the PV array. In case 1955, the programable chip may measure current from the PV Array to the Electrical Load, which may include the RC car and/or the battery. In case 1960, the programable chip may measure time. This may be used in the operation of other use cases in the calculation phase. In case 1962, the programable chip may measure the voltage at the battery, which may be used to trigger the low voltage alarm. In case 1965, the programable chip may measure current from the battery to the electrical load, usually the RC car. In case 1967, the programable chip may measure the motor temperature, to be used in triggering the overheat alarm. In case 1970, the programable chip may measure the battery temperature to be used in triggering a battery overheat alarm. In case 1972, the programable chip may measure the real-time sunlight (insolation). In case 1975 the programable chip may measure the GPS speed of the solar roller.

The calculation phase uses the programable chip to calculate various important metrics related to the operation of the solar roller. In case 1977, the programable chip calculates the solar power produced in real time by receiving the voltage at the PV array from case 1950 and the current from the PV array to the electric load from case 1955. In case 1980, the programable chip calculates the solar energy produced over time by measuring the voltage at the PV array in case 1950 and measuring time in case 1960 as well as the current sent to the load in case 1955. In case 1982, the programable chip calculates the battery power used in real time measuring the voltage at the battery in case 1962 and measuring the current from the batter to the electrical load in case 1965. Case 1987 provide indicators of direct measurements for the user to act on, including the data from cases 1967, 1970, 1972, 1975. All of the data from the calculation phase may flow to upload knowledge key 2010, whereby this information may be uploaded to a terminal (smartphone, computer, tablet, or other device) distal from the vehicle so it may be acted upon.

Additionally, the programable chip may include an interpretation phase. Interpretation phase includes case 2015, which provides for power production interpretation, case 2020 which provides for batter performance interpretation, case 2025 which provides for power consumption efficiency interpretation, and case 2030 which may provide for additional data interpretation. Interpretation according to these steps may include the ability to review historical trends, graph the data, and identify critical points and then modify the operation of the solar roller. With data and calculations from the chip, users can make key decisions about programming the chip and changing settings within the circuit, among other things. A spreadsheet, app or GUI can assist the user in managing data and making these decisions and resulting setting changes. Data from the chip is also extremely useful in making physical changes to the system (RC Car Setup) which will result in greater efficiency and higher performance. Subsequently, in the programing phase, the user may program the system to set algorithms and alerts based on optimal power management. This includes use case 2035 which relates to power production programing, use case 2040 which relates to battery performance programing, use case 2045 which relates to power consumption efficiency programing, and additional custom programing in use case 3050. These use cases interact with programable settings 1910-1945.

Throughout the following detailed description, a variety of examples are provided. Related features in the examples may be identical, similar, or dissimilar in different examples. For the sake of brevity, related features will not be redundantly explained in each example. Instead, the use of related feature names will cue the reader that the feature with a related feature name may be similar to the related feature in an example explained previously. Features specific to a given example will be described in that particular example. The reader should understand that a given feature need not be the same or similar to the specific portrayal of a related feature in any given figure or example.

In many embodiments, parts of the system are provided in devices including microprocessors. Various embodiments of the systems and methods described herein may be implemented fully or partially in software and/or firmware. This software and/or firmware may take the form of instructions contained in or on a non-transitory computer-readable storage medium. Those instructions then may be read and executed by one or more processors to enable performance of the operations described herein. The instructions may be in any suitable form such as, but not limited to, source code, compiled code, interpreted code, executable code, static code, dynamic code, and the like. Such a computer-readable medium may include any tangible non-transitory medium for storing information in a form readable by one or more computers such as, but not limited to, read only memory (ROM); random access memory (RAM); magnetic disk storage media; optical storage media; a flash memory, etc.

Embodiments of the systems and methods described herein may be implemented in a variety of systems including, but not limited to, smartphones, tablets, laptops, and combinations of computing devices and cloud computing resources. For instance, portions of the operations may occur in one device, and other operations may occur at a remote location, such as a remote server or servers. For instance, the collection of the data may occur at a smartphone, and the data analysis may occur at a server or in a cloud computing resource. Any single computing device or combination of computing devices may execute the methods described.

In various instances, parts of the method may be implemented in modules, subroutines, or other computing structures. In many embodiments, the method and software embodying the method may be recorded on a fixed tangible medium.

### Definitions

The following definitions apply herein, unless otherwise indicated.

“Substantially” means to be more-or-less conforming to the particular dimension, range, shape, concept, or other aspect modified by the term, such that a feature or component need not conform exactly. For example, a “substantially cylindrical” object means that the object resembles a cylinder, but may have one or more deviations from a true cylinder.

“Comprising,” “including,” and “having” (and conjugations thereof) are used interchangeably to mean including but not necessarily limited to, and are open-ended terms not intended to exclude additional elements or method steps not expressly recited.

Terms such as “first”, “second”, and “third” are used to distinguish or identify various members of a group, or the like, and are not intended to denote a serial, chronological, or numerical limitation.

“Coupled” means connected, either permanently or releasably, whether directly or indirectly through intervening components.

“Communicatively coupled” means that an electronic device exchanges information with another electronic device, either wirelessly or with a wire-based connector, whether directly or indirectly through a communication network.

“Controllably coupled” means that an electronic device controls operation of another electronic device.

The disclosure above encompasses multiple distinct inventions with independent utility. While each of these inventions has been disclosed in a particular form, the specific embodiments disclosed and illustrated above are not to be considered in a limiting sense as numerous variations are possible. The subject matter of the inventions includes all novel and non-obvious combinations and subcombinations of the various elements, features, functions and/or properties disclosed above and inherent to those skilled in the art pertaining to such inventions. Where the disclosure or subsequently filed claims recite “a” element, “a first” element, or any such equivalent term, the disclosure or claims should be understood to incorporate one or more such elements, neither requiring nor excluding two or more such elements.

Applicant(s) reserves the right to submit claims directed to combinations and subcombinations of the disclosed inventions that are believed to be novel and non-obvious.

Inventions embodied in other combinations and subcombinations of features, functions, elements and/or properties may be claimed through amendment of those claims or presentation of new claims in the present application or in a related application. Such amended or new claims, whether they are directed to the same invention or a different invention and whether they are different, broader, narrower or equal in scope to the original claims, are to be considered within the subject matter of the inventions described herein.

I claim:

1. A system for a configurable battery, the system comprising:
a plurality of battery cells, the plurality of battery cells not permanently welded;
a mechanical compression frame, the mechanical compression frame for holding the plurality of battery cells;
a balancing lead, the balancing lead interconnected with the plurality of battery cells, the balancing lead including one of circuitry and a microprocessor, wherein the balancing lead reads the voltage of the configurable battery at multiple points and directs current to specific cells of the plurality of battery cells.

2. The system of claim 1, wherein the plurality of battery cells are arrangeable to yield different voltages, capacities, and terminals.

3. The system of claim 1, wherein the plurality of battery cells are arrangeable in series and parallel and combinations thereof.

4. The system of claim 2, wherein the mechanical compression frame holds the plurality of battery cells in an arranged position.

5. The system of claim 4, wherein the arranged position is changeable to a second arranged position which modifies as least one of a voltage, capacity, or terminals of the configurable battery.

6. The system of claim 1, wherein the mechanical compression frame is a lattice.

7. The system of claim 6, the lattice includes a first side and a second side, each of the first side and the second side including a first and second slot, the first and second slot sized to receive an end of one of the plurality of battery cells.

8. The system of claim 7, wherein the balancing lead includes a first wire and a second wire, the first wire connectable to a first side of the lattice and the second wire connectable to the second side of the lattice.

9. The system of claim 8, further comprising a flat wire, the flat wire forming a main circuit of the configurable battery, the flat wire interconnected with the first and second wire, the flat wire arranged to yield a particular arrangement of the plurality of batteries cells, such that the plurality of battery cells are in a wired configuration selected from one of series, parallel, and a combination thereof.

10. The system of claim 9, wherein the wired configuration is changeable by rearranging the flat wire.

11. The system of claim 9, further comprising a plurality of top caps, the plurality of top caps removably holding the first and second wire against the flat wire.

12. A system for an adjustable solar array, the system comprising:
a first photovoltaic cell;
a PV Cell soldering template;
a top sheet template;
a rigid foam layer;
a plurality of array top plugs;
a plurality of connectors;
a plurality of cable ties;
a plurality of caps;
wherein, the PV Cell soldering template is arranged in relation to the first photovoltaic cell to provide soldering interconnect positions on the first photovoltaic cell, the top sheet template arranged to provide a base for the first photovoltaic cell and provide for a plurality of apertures for the plurality of array top plugs, the plurality of connectors, the plurality of cable ties, and the plurality of caps, interfacing to provide a stable frame for the adjustable solar array.

13. The system of claim 12, wherein the plurality of connectors, a plurality of array top plugs, and a plurality of caps form a crosswise frame which provides support to the rigid foam layer.

14. The system of claim 13, wherein the plurality of array top plugs provide for eight degrees of orientation for the plurality of connectors.

15. A control chip for a solar car, the control chip executing software instructions, containing software instructions that when executed cause the control chip to:
measure a PV Array voltage;
measure a PV Array current;
measure a battery voltage;
measure a battery current;
log the PV Array voltage, the PV Array current, the battery voltage, the battery current.

16. The control chip of claim 15, wherein the control chip is further configured to and caused to:
measure a battery temperature;
measure a motor temperature;
measure a gps ground speed;
measure a solar insolation;
log the battery temperature, the motor temperature, the gps ground speed, and the solar insolation.

17. The control chip of claim 15, wherein the software instructions further include that when executed cause the control chip to: hold the PV Array voltage at a selected voltage.

18. The control chip of claim 17, wherein the selected voltage is the maximum powerpoint on the IV curve of the PV array.

19. The control chip of claim 18, wherein the software instructions further include that when executed cause the control chip to: set a maximum battery voltage and control the battery voltage such that it does not exceed the maximum battery voltage.

20. The control chip of claim 19, wherein the battery voltage is controlled by disconnecting and connecting current from a solar array.
